(19) United States
(12) Patent Application Publication
(10) Pub. No.: US 2013/0229397 A1
(43) Pub. Date: Sep. 5, 2013

(54) Display Apparatus for Capturing Images and Operation Method Thereof

(71) Applicants: Tzu-Hsuan Huang, Yangmei City (TW); Jyun-Cheng Lin, Zhongli City (TW); Ru-Ji Hiseh, Taoyuan County (TW)

(72) Inventors: Tzu-Hsuan Huang, Yangmei City (TW); Jyun-Cheng Lin, Zhongli City (TW); Ru-Ji Hiseh, Taoyuan County (TW)

(73) Assignee: CHUNGHWA PICTURE TUBES, LTD., Bade City (TW)

(21) Appl. No.: 13/569,569

(22) Filed: Aug. 8, 2012

(30) Foreign Application Priority Data
Mar. 1, 2012 (TW) 101106770

(51) Int. Cl. G09G 5/00; H01L 31/02

(52) U.S. Cl. 345/207; 257/53; 257/E31.113

(57) ABSTRACT

The present invention provides a display apparatus for capturing images. The display apparatus includes a first substrate, a pixel array disposed on the first substrate, a thin film transistor array disposed in the pixel array and a photodetector array disposed in the pixel array. The pixel array includes a plurality of sub-pixels. The thin film transistor array controls image data transferred to the pixel array. When a light illuminates a sub-pixel of the pixel array, a photodetector corresponding to the sub-pixel of the photodetector array generates a leakage current in response to a gray-level of the light.

### CROSS-REFERENCE TO RELATED APPLICATIONS

This application claims priority to Taiwan Application Serial Number 101106770, filed Mar. 1, 2012, which is herein incorporated by reference.

### BACKGROUND

1. Field of Invention

The present invention relates to a webcam apparatus, and more particularly to a webcam apparatus integrated into a TFT array of a photodetector display.

2. Description of Related Art

A webcam digitalizes the signals from image sensing devices and transfers the resulting digital signals to a computer. A user watches the images captured by the webcam through the display. These images can be also transferred to another computer through the Internet.

Typically, a webcam is installed in the edge of a display. That is, a position for assembling the webcam is pre-defined in the frame of the display. Such a structure runs counter to efforts to reduce the size of displays.

### SUMMARY

The present invention provides a display apparatus for capturing images. The display apparatus at least includes a first substrate, a pixel array disposed on the first substrate, a thin film transistor array disposed in the pixel array and a photodetector array disposed in the pixel array. The pixel array includes a plurality of sub-pixels. The thin film transistor array controls image data transferred to the pixel array. When a light illuminates a sub-pixel of the pixel array, a photodetector corresponding to the sub-pixel of the photodetector array generates a leakage current in response to a gray-level of the light.

In an embodiment, the display apparatus further comprises a plurality of data lines disposed in the first substrate and arranged in a column direction and a plurality of scan lines disposed in the first substrate and arranged in a row direction, wherein the data lines cross the scan lines to define the pixel array.

In an embodiment, the display apparatus further comprises a second substrate facing the first substrate. A color layer and a black matrix are formed in the second substrate. The color layer further includes a plurality of color-units, wherein the color units include red color-units, blue color-units and green color-units arranged on the second substrate in a repeated pattern to pass red color light, blue color light and green color light respectively. The color units correspond to sub-pixels respectively. The black matrix is disposed among the color-units.

In an embodiment, each sub-pixel of the pixel array comprises a thin film transistor of the thin film transistor array and a photodetector of the photodetector array, and the black matrix is disposed in the second substrate and in locations over the thin film transistors and in locations surrounding the photodetectors.

In an embodiment, the photodetector is a thin film transistor.

In an embodiment, the thin film transistor array and the photodetector array are made by the same process.

The present invention also provides a display apparatus for capturing images. The display apparatus includes a first substrate, a second substrate and a liquid crystal layer located between the first substrate and the second substrate. The first substrate comprises a pixel array, a thin film transistor array disposed in the pixel array and a photodetector array disposed in the pixel array.

The pixel array includes a plurality of sub-pixels. The thin film transistor array controls image data transferred to the pixel array. When a light illuminates a sub-pixel of the pixel array, a photodetector corresponding to the sub-pixel of the photodetector array generates a leakage current in response to a gray-level of the light. The second substrate faces the first substrate. A color layer and a black matrix are formed in the second substrate. The color layer includes a plurality of color-units. The color units include red color-units, blue color-units and green color-units arranged on the second substrate in a repeated pattern to pass red color light, blue color light and green color light respectively, wherein color units corresponds to sub-pixels respectively, and the black matrix is disposed among the color-units.

The present invention also provides a method for capturing an image. First, the photodetector array is used to detect color lights illuminating the pixel array to generate leakage currents corresponding to the sub-pixels respectively. Next, the leakage currents are transformed to gray-levels. The gray-levels are then mixed to generate a color image of a pixel. Finally, all color images of pixels are grouped to obtain an image.

In an embodiment, the color lights include a red color light, a blue color light and a green color light. Mixing the gray-levels to generate a color image of a pixel involves mixing the gray-levels of adjacent three sub-pixels corresponding to the red color-unit, the blue color-unit and the green color-unit respectively.

Accordingly, in the present invention, an additional photodetector array is formed in a thin film transistor array. The photodetector array may capture images to make the display apparatus with capturing image function. Therefore, it is not necessary to assemble a webcam to the display apparatus, and as a result, the size of the display apparatus is significantly reduced.

### BRIEF DESCRIPTION OF THE DRAWINGS

In order to make the foregoing as well as other aspects, features, advantages, and embodiments of the present invention more apparent, the accompanying drawings are described as follows:

FIG. 1 illustrates a schematic diagram of a display apparatus according to an embodiment of the present invention.

FIG. 2 illustrates a cross-sectional view taken along line A-A′ of FIG. 1.

FIG. 3 illustrates an arrangement of color-units according to an embodiment of the present invention.

FIG. 4 illustrates a flow chart of a method for using the display apparatus of FIG. 1 to capture an image.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Typically, a webcam is assembled in the edge of a display. That is, a position for assembling the webcam is pre-defined in the frame of the display. Such a structure runs counter to efforts to reduce the size of displays. In the present invention, the pixel array of a display apparatus includes a thin film transistor array and a photodetector array. The photodetector array may capture images to make the display apparatus with capturing image function. Therefore, it is not necessary to assemble a webcam to the display apparatus, and as a result, the size of the display apparatus is significantly reduced. Moreover, the photodetector is a thin film transistor. As a consequence, the thin film transistor array and the photodetector array are made by the same process, and therefore, no additional process is needed to form the photodetector array. The following is an example to describe the claimed invention.

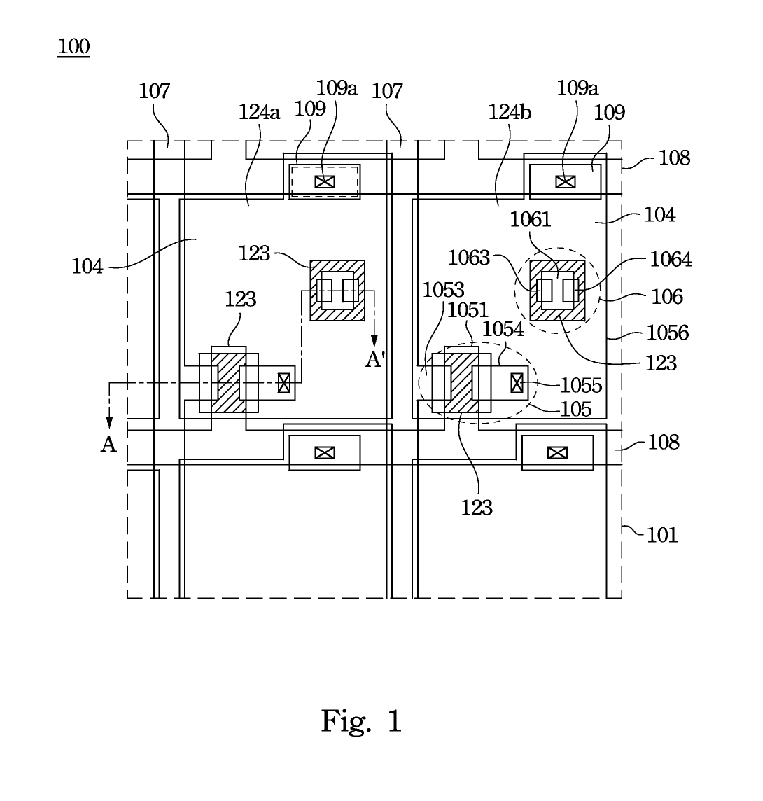

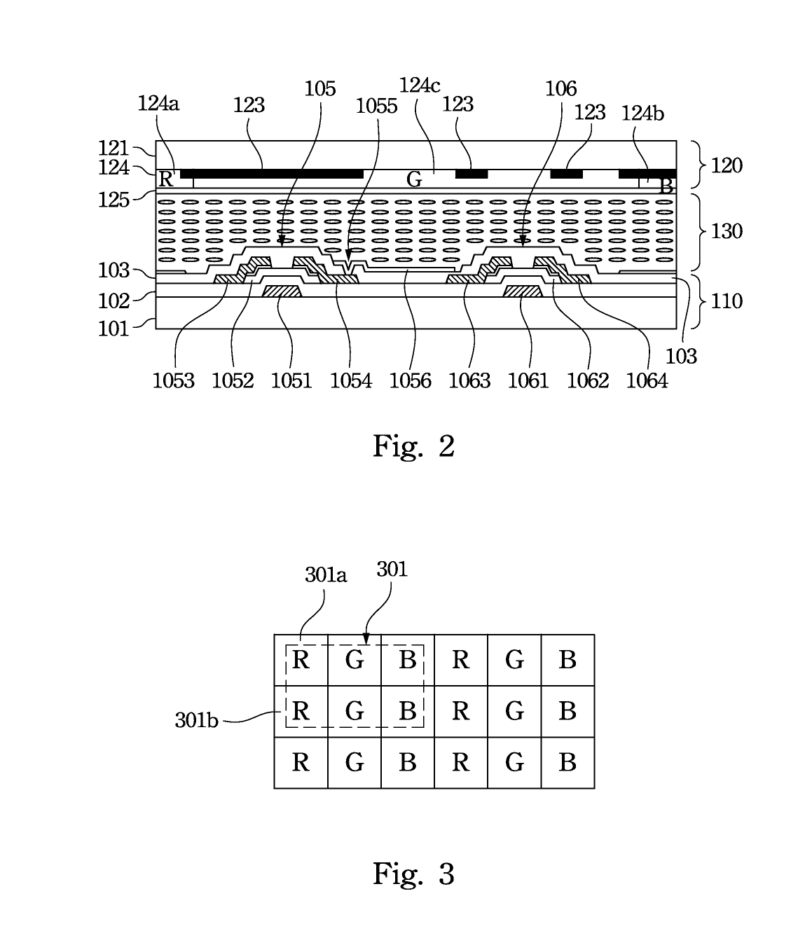

FIG. 1 illustrates a schematic diagram of a display apparatus according to an embodiment of the present invention. FIG. 2 illustrates a cross-sectional view taken along line A-A′ of FIG. 1. In this embodiment, each sub pixel in the pixel array substrate includes a first thin film transistor to serve as a switch and a second thin film transistor to serve as a photodetector for capturing an image. As illustrated in FIGS. 1 and 2, the display apparatus 100 includes a pixel array substrate 110, a filter substrate 120 and a liquid crystal molecule layer 130 located between the pixel array substrate 110 and the filter substrate 120.

The pixel array substrate 110 includes a first substrate 101 and a thin film transistor array and a photodetector array. The thin film transistor array and the photodetector array are formed on the first substrate 101. The thin film transistor array includes a plurality of first thin film transistors 105. Each first thin film transistor 105 acts as a switch. The photodetector array includes a plurality of second thin film transistors 106. Each second thin film transistor 106 acts as a photodetector to capture an image.

In the explanation to follow, one of the first thin film transistors 105 and one of the second thin film transistors 106 will be given by way of example. However, it is to be understood that the thin film transistor array and the photodetector array respectively include a plurality of first thin film transistors 105 and a plurality of second thin film transistors 106, as described above.

The first thin film transistor 105 and the second thin film transistor 106 are formed on the first substrate 101 at the same time and using the same process. Moreover, the first thin film transistor 105 and the second thin film transistor 106 have the same structure. For example, a gate electrode 1051 of the first thin film transistor 105 and a gate electrode 1061 of the second thin film transistor 106 are disposed on the first substrate 101. In this embodiment, the first substrate 101 is a glass substrate. A dielectric layer 102 is disposed on the gate electrode 1051 and the gate electrode 1061. A channel 1052 of the first thin film transistor 105 and a channel 1062 of the second thin film transistor 106 are disposed on the dielectric layer 102 and over the gate electrode 1051 and the gate electrode 1061. The channel 1052 and the channel 1062 are manufactured using amorphous silicon. Subsequently, a source electrode 1053 and a drain electrode 1054 of the first thin film transistor 105 are disposed on the channel 1052 and the dielectric layer 102, and a source electrode 1063 and a drain electrode 1064 of the second thin film transistor 106 are disposed on the channel 1062 and the dielectric layer 102. Next, a protection layer 103 is disposed on the source electrodes 1053 and 1063 and the drain electrodes 1054 and 1064. A contact hole 1055 is formed in the protection layer 103 to partially expose the drain electrode 1054 of the first thin film transistor 105. A pixel electrode 1056 is connected to the drain electrode 1054 through the contact hole 1055. In this embodiment, indium tin oxide (ITO) is used for forming the pixel electrode 1056.

The filter substrate 120 includes a second substrate 121, a black matrix 123, a color layer 124 and an ITO layer 125. The black matrix 123, the color layer 124 and the ITO layer 125 are disposed on the second substrate 121. The color layer 124 includes a plurality of each of three color-units, namely, a plurality of red color-units 124a, a plurality of blue color-units 124b and a plurality of green color-units 124c. The three color-units 124a, 124b and 124c are disposed on the second substrate 121 in a repeated pattern to allow corresponding color light to pass therethrough. Each color-unit 124a, 124b or 124c corresponds to a sub-pixel. A pixel is composed of three adjacent sub-pixels corresponding to one red color-unit 124a, one blue color-unit 124b and one green color-unit 124c respectively. The black matrix 123 is disposed between the red color-units 124a and the blue color-units 124b, and between the blue color-units 124b and the green color-units 124c to prevent light pass therethrough. The ITO layer 125 and the pixel array substrate 110 control the rotation angle of the liquid crystal molecules 130. The different rotation angles of the liquid crystal molecules 130 control the quantity of light passing through the color layer 124 to display different gray-levels of red color, blue color and green color. By mixing these colors with different gray-levels, a color image is displayed.

Moreover, in this embodiment, the black matrix 123 is also disposed in a color-unit that is over the second thin film transistor 106, and the black matrix 123 is arranged surrounding the second thin film transistor 106. As illustrated in FIG. 2, the second thin film transistor 106 is disposed in a sub-pixel corresponding to the green color-unit 124c. Accordingly, the black matrix 123 is disposed in the green color-unit 124c and is arranged surrounding the second thin film transistor 106. Therefore, only light that enters from directly above the second thin film transistor 106 (i.e., straight light) can pass through the green color-unit 124c to illuminate the second thin film transistor 106, and as a result, different color light cannot be sensed by the second thin film transistor 106. Such a structure ensures that the second thin film transistor 106 captures images that face the display.

In the above embodiment, one of the second thin film transistors 106 is disposed in each sub-pixel. However, in another embodiment, six adjacent color units are grouped together, one of the second thin film transistors 106 is alternately disposed in sub-pixels. That is, one of the second thin film transistors 106 is disposed in one of two adjacent sub-pixels corresponding to color-units with the same color. FIG. 3 illustrates an arrangement of color-units according to an embodiment of the present invention. In this embodiment, six color units located in the region 301 are grouped together. For sensing the strength of the light that illuminates the red color-units 301a and 301b, one of the second thin film transistors 106 is disposed in one of the two sub-pixels corresponding to the red color-units 301a and 301b. In another embodiment, the second thin film transistor 106 can be disposed at a position adjacent to the two sub-pixels corresponding to the red color-units 301a and 301b. That is, it is not necessary for the second thin film transistor 106 to be located in a sub-pixel. Moreover, the present invention can be applied in other types of arrangements of the color-units to dispose the second thin film transistor 106 to capture images.

As best illustrated in FIG. 1, the pixel array substrate 110 includes a plurality of data lines 107 arranged in a column direction, and a plurality of scan lines 108 arranged in a row direction. The data lines 107 cross the scan lines 108 to define a pixel matrix with a plurality of pixels. In this embodiment, each pixel is composed of three sub-pixels corresponding to a red color-unit 124a, a blue color-unit 124b and green color-unit 124c respectively. Each sub-pixel includes at least two thin film transistors, that is, a first thin film transistor 105 and a second thin film transistor 106. The first thin film transistor 105 acts as a switch, and the second thin film transistor 106 acts as a photodetector to capture an image. The first thin film transistor 105 is disposed at a location where one of the data lines 107 crosses one of the scan lines 108. The second thin film transistor 106 is disposed at a location separated from the first thin film transistor 105.

The first thin film transistor 105 includes a gate electrode 1051, a source electrode 1053 and a drain electrode 1054. The gate electrode 105 is formed on the substrate 101 and connected to the scan line 108. The source electrode 1053 is connected to the data line 107. The drain electrode 1054 is connected to a pixel electrode 1056 through a contact hole 1055. The pixel electrode 1056 is disposed in the sub-pixel 104.

The second thin film transistor 106 includes a gate electrode 1061, a source electrode 1063 and a drain electrode 1064. The first thin film transistor 105 acts as a switch, as described above. When the scan line 108 is selected to turn on the first thin film transistor 105, the data transferred in the data line 107 is transferred to the pixel electrode 1056 through the source electrode 1053 and the drain electrode 1054 to drive the liquid crystal molecule to rotate to a specific angle to pass light. The second thin film transistor 106 acts as a photodetector, as described above. Therefore, when a color light illuminates the second thin film transistor 106, a leakage current is generated. By detecting the leakage current, a gray-level of this color light is determined. In an embodiment, a conductive line is connected to the source electrode 1062 of the second thin film transistor 106 to transfer the leakage current to a detector. Moreover, the gate line 108 overlaps a storage electrode 109 to define a storage capacitor. The storage electrode 109 is connected to the pixel electrode 1056 through the contact hole 109a.

Accordingly, the red color-units 124a, the blue color-units 124b and the green color-units 124c are formed in the filter substrate 120 and in the locations corresponding to the sub-pixels 104 respectively. A black matrix 123 is also disposed in the filter substrate 120. The black matrix 123 is disposed over the first thin film transistor 105 and around second the thin film transistor 106. The red color-units 124a, the blue color-units 124b and the green color-units 124c are made using resin.

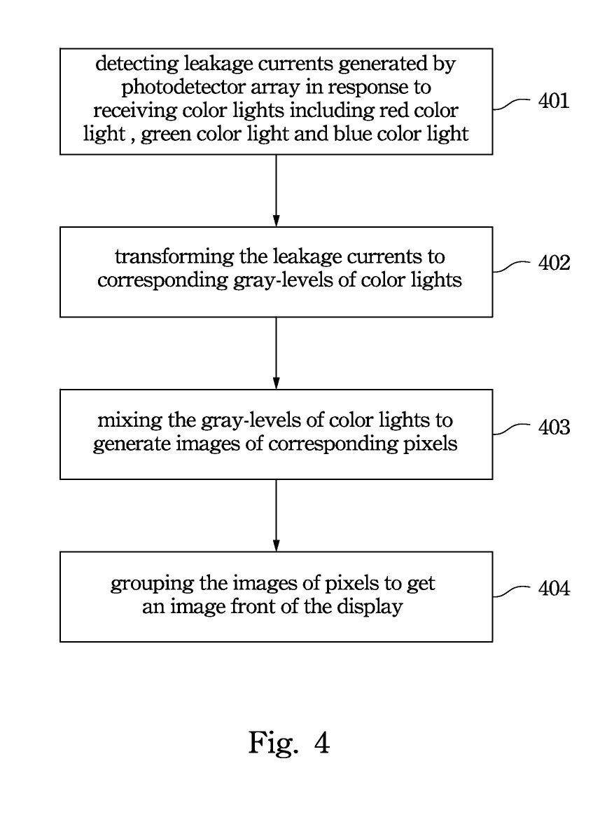

FIG. 4 illustrates a flow chart of a method for using the display apparatus 100 to capture an image. FIGS. 1-4 are referred. Each sub-pixel has a second thin film transistor 106 acting as a photodetector. When the display apparatus captures an image, in step 401, the leakage currents generated by the second thin film transistors 106 in response to color lights, a red color light, a green color light and a blue color light, are detected. In an embodiment, a red color light passes the red color-units 124a to induce the corresponding second thin film transistors 106 to generate first leakage currents. A blue color light passes the blue color-units 124a to induce the corresponding second thin film transistors 106 to generate second leakage currents. A green color light passes the green color-units 124a to induce the corresponding second thin film transistors 106 to generate third leakage currents.

Next, in step 402, each leakage current is transformed to a corresponding gray-level of a color light. In an embodiment, a conductive line is connected to the source electrode 1062 of each of the second thin film transistors 106 to transfer the corresponding leakage current to a detector. The detector detects the leakage currents and transforms the leakage currents to gray-levels. For example, the first leakage currents are transformed to corresponding gray-levels of red color light. The second leakage currents are transformed to corresponding gray-levels of blue color light. The third leakage currents are transformed to corresponding gray-levels of green color light.

In step 403, the gray-levels of red color light, the gray-levels of blue color light and the gray-levels of green color light are mixed to generate a color image of pixels. In an embodiment, the gray-levels of red color light, the gray-levels of blue color light and the gray-levels of green color light corresponding to three adjacent sub-pixels are mixed to generate a color image of a pixel. Then, in step 404, an image front of the display apparatus is obtained by grouping all the images generated by the pixels.

Accordingly, the pixel array of a display apparatus includes a first thin film transistor array and a second thin film transistor array. The first thin film transistor array includes a plurality of first thin film transistors which act as switches. The second thin film transistor array includes a plurality of second thin film transistor which act as photodetectors to capture images. Therefore, it is not necessary to assemble a webcam to the display apparatus. Hence, the size of the display apparatus is significantly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A display apparatus for capturing images, at least comprising:
a first substrate;
a pixel array disposed on the first substrate, wherein the pixel array includes a plurality of sub-pixels;
a thin film transistor array disposed in the pixel array to control image data transferred to the pixel array; and
a photodetector array disposed in the pixel array, when a light illuminates one of the sub-pixels, a photodetector of the photodetector array corresponding to the sub-pixel generates a leakage current in response to a gray-level of the light.

2. The display apparatus for capturing images of claim 1, further comprising:
a plurality of data lines disposed on the first substrate and arranged in a column direction; and
a plurality of gate lines disposed on the first substrate and arranged in a row direction, wherein the data lines cross the gate lines to define the pixel array.

3. The display apparatus for capturing images of claim 2, further comprising a second substrate facing the first substrate, wherein a color layer and a black matrix are formed on the second substrate, and the color layer further includes a plurality of color-units, red color-units, blue color-units and green color-units arranged on the second substrate in a repeated pattern to pass red color light, blue color light and green color light respectively, wherein color units corresponds to sub-pixels of the pixel array respectively, and the black matrix is disposed among the location of color-units.

4. The display apparatus for capturing images of claim 3, wherein each sub-pixel of the pixel array at least comprises a thin film transistor of the thin film transistor array and a photodetector of the photodetector array, and the black matrix is disposed in the second substrate and in location corresponding the thin film transistor and in location surrounding the photodetector.

5. The display apparatus for capturing images of claim 1, wherein the photodetector is a thin film transistor.

6. The display apparatus for capturing images of claim 1, wherein the thin film transistor array and the photodetector array are made by an identical process in the pixel array.

7. A display apparatus for capturing images, at least comprising:
a first substrate, comprising;
a pixel array including a plurality of sub-pixels;
a thin film transistor array disposed in the pixel array to control an image data transferred to the pixel array; and
a photodetector array disposed in the pixel array, wherein when a light illuminates one of the sub-pixels, a photodetector of the photodetector array corresponding to the sub-pixel generates a leakage current in response to a gray-level of the light; and
a second substrate facing the first substrate, wherein a color layer and a black matrix are formed in the second substrate, the color layer includes a plurality of color-units, wherein the color units include red color-units, blue color-units and green color-units arranged on the second substrate in a repeated pattern to pass red color light, blue color light and green color light respectively, wherein color units corresponds to sub-pixels respectively, and the black matrix is disposed among the color-units; and
a liquid crystal layer located between the first substrate and the second substrate.

8. A method for capturing an image according to a liquid crystal display of claim 1, at least comprising:
detecting leakage currents generated by the photodetector array in response to receiving color lights respectively in the sub-pixels;
transforming the leakage currents to gray-levels;
mixing the gray-levels to generate a color image of a pixel; and
grouping all color images of pixels to obtain an image.

9. The method of claim 8, wherein the color lights comprise a red color light, a blue color light and a green color light.

10. The method of claim 9, wherein mixing the gray-levels to generate a color image of a pixel comprises mixing the gray-levels of adjacent three sub-pixels corresponding to the red color-unit, the blue color-unit and the green color-unit respectively.
